(19) United States
(12) Patent Application Publication
(10) Pub. No.: US 2026/0182476 A1
(43) Pub. Date: Jun. 25, 2026

(54) DIRECT BONDING METHODS AND STRUCTURES

(71) Applicant: ADEIA SEMICONDUCTOR BONDING TECHNOLOGIES INC., San Jose, CA (US)

(72) Inventor: Cyprian Emeka Uzoh, San Jose, CA (US)

(21) Appl. No.: 19/329,438

(22) Filed: Sep. 15, 2025

Related U.S. Application Data
(63) Continuation of application No. 17/452,753, filed on Oct. 28, 2021, now Pat. No. 12,424,584.
(60) Provisional application No. 63/107,228, filed on Oct. 29, 2020.

(51) Int. Cl. H10W 99/00; H10W 80/00

(52) U.S. Cl. CPC H10W 99/00; H10W 80/016; H10W 80/312; H10W 80/327

(57) ABSTRACT

A bonding method can include polishing a first bonding layer of a first element for direct bonding, the first bonding layer comprises a first conductive pad and a first non-conductive bonding region. After the polishing, a last chemical treatment can be performed on the polished first bonding layer. After performing the last chemical treatment, the first bonding layer of the first element can be directly bonded to a second bonding layer of a second element without an intervening adhesive, including directly bonding the first conductive pad to a second conductive pad of the second bonding layer and directly bonding the first non-conductive bonding region to a second nonconductive bonding region of the second bonding layer. No treatment or rinse is performed on the first bonding layer between performing the last chemical treatment and directly bonding.

### CROSS-REFERENCE TO RELATED APPLICATIONS

This application is a continuation of U.S. patent application Ser. No. 17/452,753, filed Oct. 28, 2021, which claims priority to U.S. Provisional Ser. No. 63/107,228 , filed Oct. 29, 2020, the entire contents of which are hereby incorporated by reference herein in their entirety and for all purposes.

### BACKGROUND

### Field

The field relates to direct bonding methods and structures.

### Description of the Related Art

The demand for more compact physical arrangements of microelectronic elements such as integrated chips and device dies has become even more intense with the rapid progress of portable electronic devices, the expansion of the Internet of Things, nano-scale integration, subwavelength optical integration, and more. Merely by way of example, devices commonly referred to as “smart phones” integrate the functions of a cellular telephone with powerful data processors, memory and ancillary devices such as global positioning system receivers, electronic cameras, and local area network connections along with high-resolution displays and associated image processing chips. Such devices can provide capabilities such as full internet connectivity, entertainment including full-resolution video, navigation, electronic banking, sensors, memories, microprocessors, healthcare electronics, automatic electronics, and more, all in a pocket-size device. Complex portable devices require packing numerous chips and dies into a small space.

Microelectronic elements often comprise a thin slab of a semiconductor material, such as silicon or gallium arsenide or others. Chips and dies are commonly provided as individual, prepackaged units. In some unit designs, the die is mounted to a substrate or a chip carrier, which is in turn mounted on a circuit panel, such as a printed circuit board (PCB). Dies can be provided in packages that facilitate handling of the die during manufacture and during mounting of the die on the external substrate. For example, many dies are provided in packages suitable for surface mounting. Numerous packages of this general type have been proposed for various applications. Most commonly, such packages include a dielectric element, commonly referred to as a “chip carrier” with terminals formed as plated or etched metallic structures on the dielectric. The terminals typically are connected to the contact pads (e.g., bond pads or metal posts) of the die by conductive features such as thin traces extending along the die carrier and by fine leads or wires extending between the contacts of the die and the terminals or traces. In a surface mounting operation, the package may be placed onto a circuit board so that each terminal on the package is aligned with a corresponding contact pad on the circuit board. Solder or other bonding material is generally provided between the terminals and the contact pads. The package can be permanently bonded in place by heating the assembly so as to melt or “reflow” the solder or otherwise activate the bonding material.

Many packages include solder masses in the form of solder balls that are typically between about 0.025 mm and about 0.8 mm (1 and 30 mils) in diameter, and are attached to the terminals of the package. A package having an array of solder balls projecting from its bottom surface (e.g., surface opposite the front face of the die) is commonly referred to as a ball grid array or “BGA” package. Other packages, referred to as land grid array or “LGA” packages are secured to the substrate by thin layers or lands formed from solder. Packages of this type can be quite compact. Certain packages, commonly referred to as “chip scale packages,” occupy an area of the circuit board equal to, or only slightly larger than, the area of the device incorporated in the package. This scale is advantageous in that it reduces the overall size of the assembly and permits the use of short interconnections between various devices on the substrate, which in turn limits signal propagation time between devices and thus facilitates operation of the assembly at high speeds.

Semiconductor dies can also be provided in “stacked” arrangements, wherein one die is provided on a carrier, for example, and another die is mounted on top of the first die. These arrangements can allow a number of different dies to be mounted within a single footprint on a circuit board and can further facilitate high-speed operation by providing a short interconnection between the dies. Often, this interconnect distance can be only slightly larger than the thickness of the die itself. For interconnection to be achieved within a stack of die packages, interconnection structures for mechanical and electrical connection may be provided on both sides (e.g., faces) of each die package (except for the topmost package). This has been done, for example, by providing contact pads or lands on both sides of the substrate to which the die is mounted, the pads being connected through the substrate by conductive vias or the like.

Dies or wafers may also be stacked in other three-dimensional arrangements as part of various microelectronic packaging schemes. This can include stacking layers of one or more dies or wafers on a larger base die or wafer, stacking multiple dies or wafers in vertical or horizontal arrangements, or stacking similar or dissimilar substrates, where one or more of the substrates may contain electrical or non-electrical elements, optical or mechanical elements, and/or various combinations of these. Dies or wafers may be bonded in a stacked arrangement using various bonding techniques, including direct dielectric bonding, non-adhesive techniques, such as ZiBond® or a hybrid bonding technique, such as DBI®, both available from Invensas Bonding Technologies, Inc. (formerly Ziptronix, Inc.), an Xperi company (see for example, U.S. Pat. Nos. 6,864,585 and 7,485,968, which are incorporated herein in their entirety). When bonding stacked dies using a direct bonding technique, it is usually desirable that the surfaces of the dies to be bonded be extremely flat and smooth. For instance, in general, the surfaces should have a very low variance in surface topology, so that the surfaces can be closely mated to form a lasting bond. For example, it is generally preferable that the variation in roughness of the bonding surfaces be less than 3 nm and preferably less than 1.0 nm.

Some stacked die arrangements are sensitive to the presence of particles or contamination on one or both surfaces of the stacked dies. For instance, particles remaining from processing steps or contamination from die processing or tools can result in poorly bonded regions between the stacked dies, or the like. Extra handling steps during die processing can further exacerbate the problem, leaving behind unwanted residues.

### BRIEF DESCRIPTION OF THE DRAWINGS

FIG. 1 is a flow chart illustrating a process for directly bonding first and second elements.

FIGS. 2A-2D schematically illustrate a bonding method according to various embodiments.

FIG. 3 is a flowchart illustrating an example process for forming a bonded structure, according to various embodiments.

FIG. 4 is a flowchart illustrating another example process flow for forming a bonded structure, according to various embodiments.

FIG. 5 is a flowchart illustrating another example process flow for forming a bonded structure, according to various embodiments.

FIG. 6 is a flowchart illustrating another example process flow for forming a bonded structure, according to various embodiments.

FIG. 7 is a flowchart illustrating another example process flow for forming a bonded structure, according to various embodiments.

### DETAILED DESCRIPTION

Two or more semiconductor elements (such as integrated device dies, wafers, etc.) may be stacked on or bonded to one another to form a bonded structure. Conductive contact pads of one element may be electrically connected to corresponding conductive contact pads of another element. Any suitable number of elements can be stacked in the bonded structure. As used herein, contact pads may include any suitable conductive feature within an element configured to bond (e.g., directly bond without an adhesive) to an opposing conductive feature of another element. For example, in some embodiments, the contact pad(s) may comprise a discrete metallic contact surface formed in a bonding layer of an element. In some embodiments, the contact pad(s) may comprise exposed end(s) of a through-substrate via (TSV) that extends at least partially through an element.

In some embodiments, the elements are directly bonded to one another without an adhesive. In various embodiments, a dielectric field region (also referred to as a nonconductive bonding region) of a first element (e.g., a first semiconductor device die with active circuitry) can be directly bonded (e.g., using dielectric-to-dielectric bonding techniques) to a corresponding dielectric field region of a second element (e.g., a second semiconductor device die with active circuitry) without an adhesive. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can be directly bonded to corresponding conductive contact pads of the second element. For example, a hybrid bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments and, subsequently, the bonded structure can be annealed. Upon annealing, the laterally confined contact pads can expand and contact one another to form a metal-to-metal direct bond. Beneficially, the use of Direct Bond Interconnect, or DBI®, techniques can enable high density of pads connected across the direct bond interface (e.g., small or fine pitches for regular arrays). In various embodiments, the contact pads can comprise copper or copper alloys, although other metals may be suitable. In some embodiments, the contact pads can be arranged in an array having a regular or irregular pitch. In some embodiments, to the extent the contacts are regularly spaced from one other across the element, or across groups within the element, the pitch of the contact pads may be less 40 microns, less than 10 microns, or less that 2 microns. For some embodiments, the ratio of the pitch of the contact pads to a dimension (e.g., a diameter) of the contact pad can be less than 5, less than 3, or less than 2.

In various embodiments, the contact pads can be formed in respective first and second arrays of pads on the first and second elements. If any debris or surface contaminant is present at the surface of the first or second elements, voids may be created at the bond interface, or debris may intervene between opposing contact pads. In addition, reactant byproducts generated during bonding and annealing, e.g. hydrogen and water vapor, may also form voids at the bond interface. These voids may effectively inhibit the joining of particular contact pads in the vicinity, creating openings or other failures in the bond. For example, any void larger than the pad diameter (or pitch) can potentially create an opening and direct bond failure. In some embodiments, depending on the location of the voids, voids that are comparable in size to or smaller than the pad diameter (at least partially located over pad) may be the source of failure in the bonded structure or structures.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer).

As an example, in one embodiment, the first element can comprise a singulated device die, and the second element can comprise a wafer. In such an embodiment, the first element may be initially provided in wafer form or on a larger dielectric substrate and singulated to form the singulated first element. However, the singulation process and/or other processing steps may produce debris that can contaminate the planar bonding surface, which can leave voids and/or defects when two elements are bonded. Accordingly, prior to singulation, a protective layer can be provided over the bonding surface before singulation and direct bonding in order to prevent debris from contaminating the bonding surface. The protective layer can comprise an organic or inorganic layer (e.g., a photoresist or spin on glass) that is deposited (e.g., spin coated onto) the bonding surface. Additional details of the protective layer may be found throughout U.S. Pat. No. 10,714,449, the entire contents of which are incorporated by reference herein in their entirety and for all purposes. The wafer containing the first element can be singulated using any suitable method. The protective layer over the bonding surface can beneficially protect the bonding surface from debris.

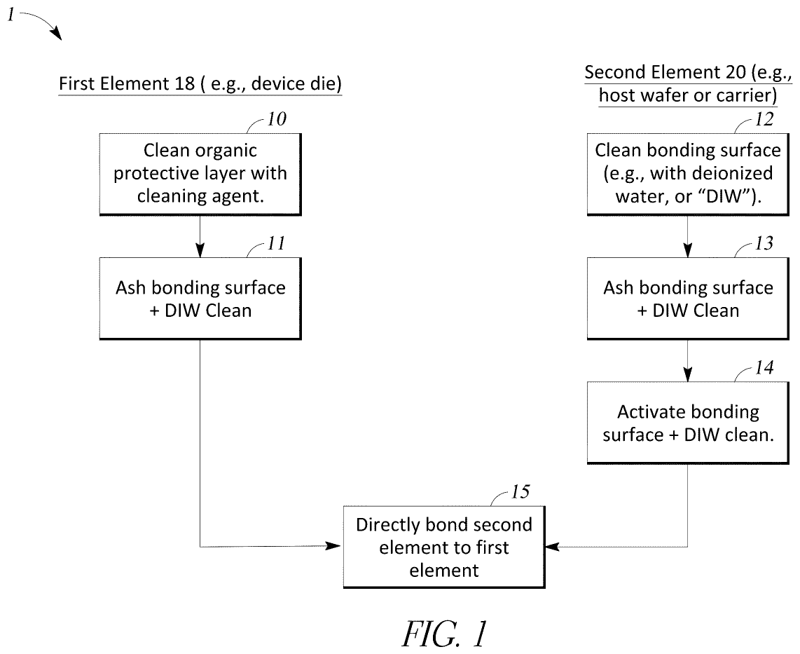

FIG. 1 is a flow chart illustrating a process 1 for directly bonding first and second elements. In FIG. 1, the first element can comprise a singulated die, e.g., a singulated device die, and the second element can comprise a substrate, such as a host wafer or carrier. In other embodiments, the second element can comprise a second die. As explained above, prior to singulation, a protective layer (e.g., an organic protective layer) can be provided over the wafer to protect the wafer during singulation or dicing. As shown in block 10 of FIG. 1, the organic protective layer on the singulated first element can be cleaned from the bonding surface with a cleaning agent, for example such as a suitable solvent, an alkaline solution or other suitable cleaning agent as recommended by the supplier of the protective layer. The protective layer cleaning agent can be selected such that it does not substantially roughen the smooth bonding surface of the dielectric layer and does not substantially etch the metal of the contact pad to increase the recess of the pad metal. An excessive pad recess may form a recess that is too deep, which may prevent (or reduce the strength of) pad-to-pad bonding at the appropriate annealing conditions (e.g., annealing temperature and times). For example, the annealing temperature may vary in a range of 150° C. to 350° C., or higher. The annealing times may range between 5 minutes to over 120 minutes. The cleaning agent can be applied by a fan spray of the liquid cleaning agent or other methods known to those having skill in the art. Turning to block 11, the cleaned bonding surface can be ashed (e.g., using an oxygen plasma) and cleaned with deionized water (DIW). The ashing step of block 11 can remove any residual organic material from the protective layer. In some embodiments, the cleaned first element can be activated before direct bonding.

In a block 12, the second element (which can comprise a wafer in this embodiment, but in other embodiments can comprise an integrated device die) can also be cleaned with DIW. In a block 13, the bonding surface can be ashed (e.g., using an oxygen plasma) to remove any organic material and cleaned with DIW. Further, as shown in block 14 of FIG. 1, the bonding surface of the second element can be activated. In various embodiments, the activation can comprise exposing the bonding surface of the second element to a plasma, such as a nitrogen-containing plasma. In other embodiments, the activation can comprise exposing the bonding surface of the second element to an oxygen plasma. As explained above, the activation process (which may also terminate the bonding surface) can break bonds at the bonding surface and replace the broken bonds with chemical species that enhance the bonding energy of the direct bond. As shown in block 14 of FIG. 1, the activated surface can be cleaned with DIW, which may serve to wash any residue away before bonding without degrading the bonding surface of the first or second element.

In a block 15, the first and second elements can be brought together to directly contact one another at room temperature. As explained herein, the nonconductive bonding regions of the first and second elements can spontaneously bonds at room temperature, without application of external pressure, and without application of a voltage. The structure can be annealed to cause the conductive contact pads to expand and form electrical connections and to also increase the bonding energy between the respective bonded nonconductive bonding regions of the first and second elements.

In the bonding arrangement shown in FIG. 1, only the second element may be activated before direct bonding. As explained in U.S. Pat. No. 10,727,219, which is incorporated by reference herein in its entirety and for all purposes, the bonded strength between two elements may be sufficiently strong when only one of the two elements is activated before bonding. However, in other arrangements, both the first element and the second element may be activated prior to bonding, or, alternatively, only the first element may be activated before bonding.

In some cases, the direct bond that results from the process 1 shown in FIG. 1 may include voids and/or other defects at the bond interface. For example, when the first and second elements are brought together, a bonding wave may travel from the center of the elements outwards from where the initial contact occurred. When the bonding wave travels sufficiently fast, the wave may travel non-symmetrically radially outwards from the center of the bonded elements to the edges of the elements. In such cases, the bonding wave may prematurely wrap around itself so as to trap the void or escaping gas (e.g., air bubble or bubbles) along the bond interface. It can be beneficial to modulate the motion of the bonding wave so that voids are eliminated or reduced, and to generally improve the bonding energy between the first and second elements. Also, it may be advantageous to increase the bonding energy of the bonded elements. High bond energy between bonded elements improves the reliability of the bonded structure.

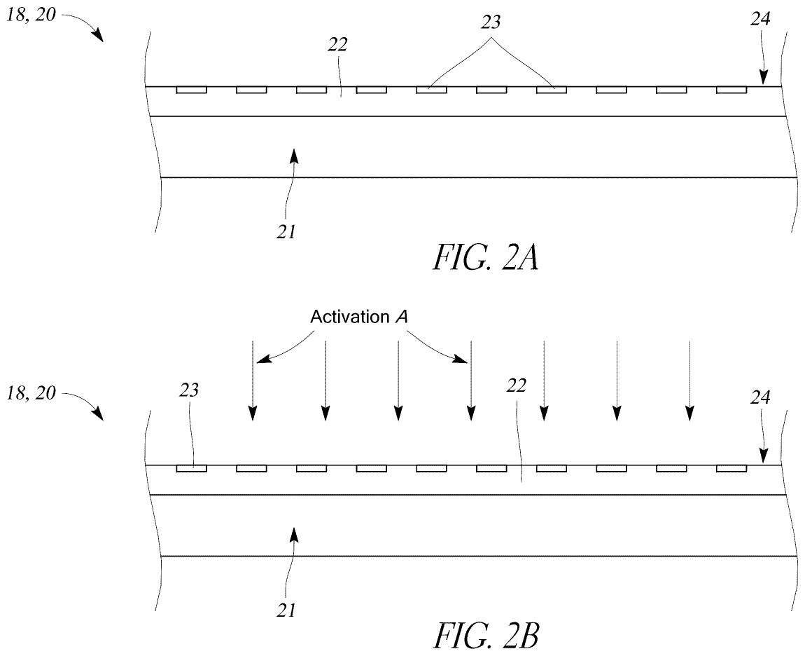

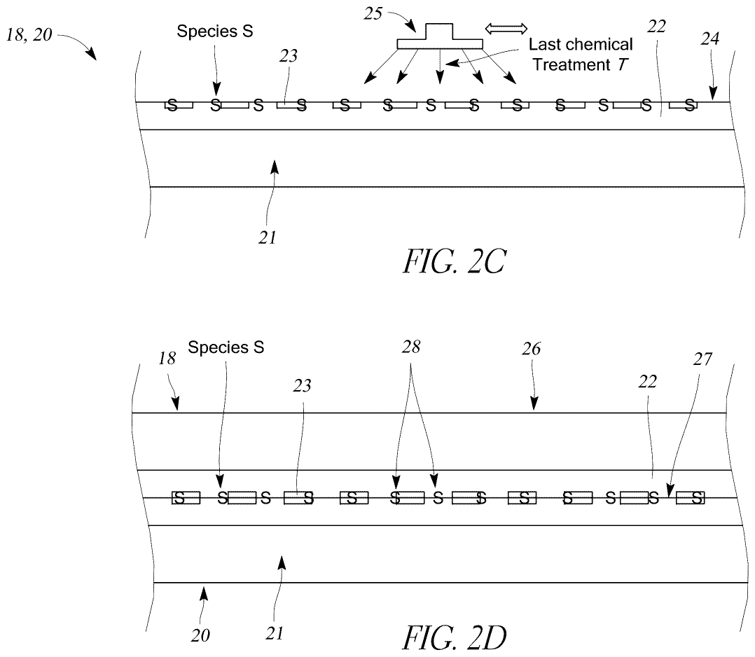

FIGS. 2A-2D schematically illustrate a bonding method according to various embodiments. FIG. 2A illustrates a schematic side sectional view of the first element 18 or the second element 20. The first or second element 18, 20 can comprise an integrated device die or a wafer. Although not shown in FIGS. 2A-2D, in some embodiments, the element in wafer form may be coated with a protective layer prior to singulation to protect the element during the singulation process. As explained above in connection with FIG. 1, after singulation, the protective layer can be removed with a suitable cleaning formulation, and the element can be ashed to remove debris. Thus, in FIG. 2A, the first or second element 18, 20 is shown without the protective layer.

The element 18, 20 can comprise a base portion 21, which can comprise a semiconductor material, such as a silicon device for example. Active devices (e.g., transistors) and/or passive devices can be formed in or on the base portion 21. A bonding layer 24 can be provided (e.g., deposited) on the base portion 21. In various embodiments, the bonding layer 24 can comprise a nonconductive bonding region 22 (e.g., a dielectric field region) that includes an inorganic dielectric in some embodiment. In other embodiments, the nonconductive bonding region 22 can comprise an organic dielectric. For example, in some embodiments, the nonconductive bonding region 22 can comprise silicon oxide or a silicon-containing dielectric layer such as SiN, SiOₓN_{y}, silicon carbide, silicon carbonitride or silicon carboboride, etc. The nonconductive bonding region 22 may also comprise non-silicon dielectric layer for example, ceramic layers, such as alumina or sapphire, zirconia, boron carbide, boron oxide, aluminum nitride, piezoceramics, ferro ceramics, zinc oxide, zirconium dioxide, titanium carbide, glass ceramics and their various combinations.

The bonding layer 24 can further include a plurality of conductive contact pads 23 formed in the nonconductive bonding region 22. In various embodiments, the contact pads 23 can comprise copper or copper alloy, or nickel or nickel alloys, although other suitable metals can be used. The bonding layer 24 can comprise a bonding surface that can be cleaned and polished or planarized (e.g., using chemical mechanical polishing, or CMP) to a very high degree of smoothness. Exposed surfaces (e.g., upper surfaces) of the contact pads 23 may be recessed relative to the exterior surface of the nonconductive bonding region 22. For example, the exposed surfaces can be recessed relative to the exterior surface of the nonconductive bonding region 22 by less than 20 nm, less than 15 nm, or less than 10 nm, for example, recessed in a range of 2 nm to 20 nm, or in a range of 4 nm to 10 nm.

Turning to FIG. 2B, the bonding layer 24 can be activated for direct bonding after the polishing. For example, the bonding layer 24 can be exposed to a plasma comprising an activation species A. In some embodiments, the plasma can comprise a nitrogen-containing species. For example, in embodiments in which the nonconductive bonding region 22 comprises silicon oxide or silicon carbonitride, the use of a nitrogen-containing plasma for activation can provide strong bonding energies. In other embodiments, the plasma can comprise an oxygen-containing plasma. For example, in embodiments in which the nonconductive bonding region 22 comprises silicon nitride or silicon carbonitride, the use of an oxygen-containing plasma for activation can provide strong bonding energies.

In FIG. 2C, a last chemical treatment T can be performed to react with the polished and activated bonding layer 24. The last chemical treatment T can comprise a liquid solution (e.g., an aqueous solution). For example, in some embodiments, a dispersion device 25, such as a sprayer, can be used to rinse the bonding layer 24 with a glass-forming chemical species S. The glass-forming species S can be selected to have a composition and/or concentration that does not etch the pads 23 (e.g., that does not significantly etch copper). In various embodiments, the glass-forming chemical species S can comprise a liquid solution that includes at least one of boron, phosphorus, manganese, arsenic, peroxide, selenium, carbon, and fluorine or a fluoride source. In some embodiments, the glass-forming chemical species S can include a liquid solution that includes only one of boron, phosphorus, manganese, arsenic, peroxide, selenium, carbon, and fluorine or a fluoride source. In other embodiments, the glass-forming chemical species S can include a liquid solution that includes more than one of boron, phosphorus, manganese, arsenic, peroxide, selenium, carbon, and fluorine or a fluoride source. In some embodiments, the glass-forming chemical species S can comprise very dilute buffered hydrofluoric acid (BHF) with a pH between 2 to 6.5, for example, in a range of 4 to 6.5. In some embodiments, the glass-forming (or glass-enhancing) chemical species S can comprise very dilute boric acid or selenious acid. In some embodiments, the glass-forming chemical species can comprise hydrogen peroxide solution. The hydrogen peroxide solution may vary in a range of 0.3 % to 50%, e.g., in a range of 1% to 15%. In some embodiments, the species S can comprise one or more of tetramethylammonium hydroxide (C₄H₁₂N), tert-butylammonium hydroxide, tetraethylammonium hydroxide, ethyltrimethylammonium hydroxide, boric anhydride, boric acid, borane-ammonia (H₆BN), borane trimethylamine complex, borane dimethyl amine complex (C₂H₁₀BN), tetrahydroxydiboron solution, mannitol (C₆H₁₄O₆, which can include multiple (6) hydroxyl groups), and ascorbic acid (C₆H₈O₆). After forming the glass enhancing layer over the bonding surface, the metal pad surface may be selectively cleaned prior to bonding. In some embodiments, the introduction of a peroxide-containing species at the bond interface can increase the bond energy of the bonded elements and also reduce voids at the bonding interface. In some embodiments, the glass-forming chemical species S can comprise dilute phosphoric acid. The concentration of the glass-forming species S can be very dilute so as to avoid overetching the conductive contact pads. For example, the glass-forming species S can be diluted in a solution (e.g., in an aqueous solution or a non-aqueous solution) to have a concentration in a range of 1 ppm to 10,000 ppm, in a range of 1 ppm to 1,000 ppm, in a range of 1 ppm to 500 ppm, in a range of 1 ppm to 400 ppm, in a range of 5 ppm to 10,000 ppm, in a range of 5 ppm to 4,000 ppm, or in a range of 5 ppm to 500 ppm. In various embodiments, the last chemical treatment can have a pH of at least 3.1, or of at least 3.3. For example, the last chemical treatment can have a pH in a range of 3.3 to 10, or in a range of 4 to 10.

In some embodiments, the glass-forming chemical species S can comprise tetramethyl ammonium hydroxide. The pH of the tetramethyl ammonium hydroxide can be in a range of 7 to 11, or in a range of 7 to 10. A concentration of the tetramethyl ammonium hydroxide can be less than 200 ppm, or less than 100 ppm. For example, a concentration of the tetramethyl ammonium hydroxide can be in a range of 5 ppm to 75 ppm, or in a range of 5 ppm to 60 ppm.

The last chemical treatment T of FIG. 2C can comprise a liquid treatment that chemically reacts with the bonding layer 24 and/or with the bonding layer 24 of the other element during bonding. In some embodiments, for example, the liquid treatment can react so as to reduce a size of voids at the bonding surface(s). For example, in conventional wafer to wafer (W2W) bonding operations, the planar bonding surface of the first and second elements 18, 20 may be cleaned with DIW or any suitable cleaning agent. The cleaned surfaces may be ashed and rinsed with DIW prior to the activation step. As explained above, the activation step may comprise exposing the bonding surfaces of the first and/or second elements 18, 20 to a nitrogen-containing plasma, a water vapor plasma, or various combinations of both types of plasma. After the activation process, the activated bonding surfaces can be thoroughly rinsed with DIW before bonding the wafers. In the disclosed embodiments, the last chemical treatment may not comprise pure water, e.g., pure DIW.

For example, in a wafer-to-wafer (W2W) bonding process of silicon dioxide planar bonding surfaces, the first and/or second elements 18, 20 may be cleaned with DIW or any suitable cleaning agent. The cleaned planar silicon oxide surfaces may be ashed (e.g., the ashing process may comprise the use of water vapor plasma as described herein) and, after the ashing step, the ashed surface of the first and/or second elements 18, 20 may be rinsed with DIW prior to the W2W bonding operation, which may be performed without the activation step. In some embodiments, after the ashing step, the ashed surface of the first and/or second elements may be exposed to the last chemical treatment T before the W2W bonding operation. The last chemical treatment T may comprise a glass-forming chemical species S, for example, very dilute tetramethyl ammonium hydroxide. The pH of the tetramethyl ammonium hydroxide can be in a range of 7 to 11, or in a range of 7 to 10 prior to the W2W bonding operation. As an example, the last chemical treatment T may comprise dipping the ashed surface of the first and/or second elements 18, 20 in the chemical species S, or the chemical species S may be sprayed or coated on the ashed surface with the dispersion device 25. For example, the chemical species S may be sprayed or coating for a time in a range of 5 s to 120 s before spin drying species S on the ashed surface or surfaces. Thus, the chemical species S can be applied by exposing the ashed surface to the chemical species S and drying the species S from the exposed surface without the use of any other cleaning agent. In one example, the measured bond energy of a bonded pair of planar silicon oxide surfaces that were ashed and rinsed with DIW and annealed at 150° C. for 15 minutes was between 500 mJ/m² to 700mJ/m². By contrast, the measured bond energy of a bonded pair of planar silicon oxide surfaces that were ashed and exposed to a very dilute tetramethyl ammonium hydroxide prior to the annealing step was between 2200 mJ/m² to 2400mJ/m², which provides a substantially stronger direct bond as compared to surfaces that are rinsed with DIW before bonding. In this example, the application of the last chemical treatment process to treat the ashed bonding surfaces of the first and/or second elements 18, 20 can improve the bond strength or bond energy of the bonded structure by a factor of at least 3. In some embodiments, the last chemical treatment may be applied to the activated surfaces of the first and/or second elements directly prior to the bonding step.

The last chemical treatment may comprise a chemically active species S that reacts with or adsorbs to the activated surface of the bonding layer (or with the bonding surface of the other element to which it is to be bonded) and provides a high bonding energy when broad into contact with the bonding surface of the other element. In various embodiments, no additional treatments are performed between the last chemical treatment and the direct bonding. For example, there may be no additional liquid treatments (e.g., no DIW or other pure water rinse) after the last chemical treatment.

In some embodiments, more than one type of chemical species S can be applied for the last chemical treatment for the cleaned, ashed, or activated surfaces of the first and/or second elements 18, 20. As an example, last chemical treatment applied to the cleaned bonding surface of the first element 18 can comprise chemical species A. For example, species A may render the bonding surface alkaline, as in a treatment with very dilute tetramethyl ammonium hydroxide. The last chemical treatment applied to the cleaned bonding surface of the second element 20 can comprise chemical species B. For example, species B may render the bonding surface acidic, as in a treatment with very buffered HF. After the treatment steps, the treated bonding surface of the first and second elements 18, 20 can be bonded and annealed at to increase the bond strength of the interface between the first and second bonded elements 18, 20. For element-to-element stacking operations, a bonding surface may be formed on the backside of the first or second element 18, 20. Forming the bonding surface on the backside of the second element 20, for example, may comprise thinning and polishing the second element 20 from the backside, forming a planar dielectric bonding surface with embedded conductive layer on the second element 20, ashing or activating the bonding surface on the backside of the second element 20, and performing the last chemical treatment prior to bonding a third element (not shown) on the backside of the second element 20. The stacked bonded elements may be annealed before subsequent operations. In one embodiment, the stacked bonded elements may not be annealed before subsequent processes, and the stacked bonded elements may be thoroughly rinsed before subsequent operations. One of the subsequent operations for example may comprise of singulating the bonded stacked elements or examples may include forming conductive structures on the lower or upper surface of the bonded stacked elements. The conductive structure may comprise a planar conductor or a flowable conductor or both.

Turning to FIG. 2D, the first and second elements 18, 20 can be brought together in contact with one another to form a bonded structure 26 including direct bonds along a bond interface 27 between the nonconductive bonding regions 22 of the first and second elements 18, 20. The bonded structure 26 can be annealed, and the contact pads 23 can extend to make direct contact and an electrical connection along the bond interface 27. The bond interface 27 can comprise sediment from the last chemical treatment T. For example, as shown in FIG. 2D, sediment 28 of the glass-forming species S introduced in FIG. 2C may be present at the bond interface 27. For example, depending on the particular solution used in the last chemical treatment T, the glass-forming chemical species S at the bonding interface 27 can comprise at least one of boron, phosphorus, manganese, arsenic, peroxide, selenium, carbon, and fluorine or a fluoride source. In various embodiments, the bond interface 27 may additionally include a signature of the activation process A. For example, in some embodiments, the bond interface 27 may additionally include nitrogen and/or oxygen concentration peaks at or near the interface 27. The concentration of species S at the bonding interface 27 between the first and second elements 18, 20 can exceed the nominal background level of species S found at other dielectric-to-dielectric interfaces below or within the direct bonding layer.

Beneficially, the glass-forming species S can improve the bond energy between the bonded elements 18, 20 in the bonded structure 26 by reacting with the activated surface of the first and second elements 18, 20. As explained above, the glass-forming species S may be provided in a dilute concentration such that the conductive contact pads 23 are not overetched, which can improve the bonding and electrical connection between bonded pads 23. Overetching can increase the amount of the recess between the exposed upper surface of the pads 23 and the exterior surface of the nonconductive bonding region 22, which can reduce the reliability of the electrical connection. The glass-forming species S may also suppress oxide formation on the conductive contact pads 23. Moreover, the bonding wave can be slowed relative to the arrangement of FIG. 1, such that there are fewer voids and/or defects along the bond interface 27.

As explained herein, the first and second elements 18, 20 can be directly bonded to one another without an adhesive, which is different from a deposition process. The bond interface 27 between first and second elements 18, 20 can accordingly comprise a non-deposited interface. Further, directly bonded structures 26, unlike deposited layers, can include a defect region along the bond interface 27 in which nanovoids are present. The nanovoids may be formed due to activation of the bonding surfaces (e.g., exposure to a plasma). As explained above, the bond interface 27 can include a higher concentration of treatment element from the activation A and/or last chemical treatment processes T relative to deeper locations in the bonding layers 24 (typically inorganic dielectrics). For example, in embodiments that utilize a nitrogen plasma and/or ammonium dip for activation, a nitrogen peak can be formed at the bond interface 27 for silicon oxide-based bonding layers, relative to the bulk of the bonding layers 24. Nitrogen activation can also leave an oxygen peak at the interface surfaces of silicon nitride and silicon carbonitride bonding layers, relative to the bulk. In embodiments that utilize an oxygen plasma for activation, an oxygen peak can be formed at the bond interface 27. In some embodiments, the bond interface 27 can comprise silicon oxynitride, silicon oxycarbonitride, or silicon carbonitride. As explained herein, the direct bond can comprise a covalent bond, which is stronger than van Der Waals bonds. The bonding layers 24 can also comprise polished surfaces that are planarized to a high degree of smoothness.

In addition to N or O peaks from activation, in embodiments described herein, residue from the glass-forming species S may also be at the interface 27. For example, the interface 27 may include at least one of boron, phosphorus, manganese, arsenic, peroxide, selenium, carbon, and fluorine or a fluoride source.

In various embodiments, the metal-to-metal bonds between the contact pads 23 can be joined such that copper grains grow into each other across the bond interface 27. In some embodiments, the copper can have grains oriented along the 111 crystal plane for improved copper diffusion across the bond interface. The bond interface 27 can extend substantially entirely to at least a portion of the bonded contact pads 23, such that there is substantially no gap between the nonconductive bonding regions 22 at or near the bonded contact pads 23. In some embodiments, a barrier layer (not shown) may be provided under the contact pads (e.g., which may include copper). In other embodiments, however, there may be no barrier layer under the contact pads 23, for example, as described in US 2019/0096741, which is incorporated by reference herein in its entirety and for all purposes.

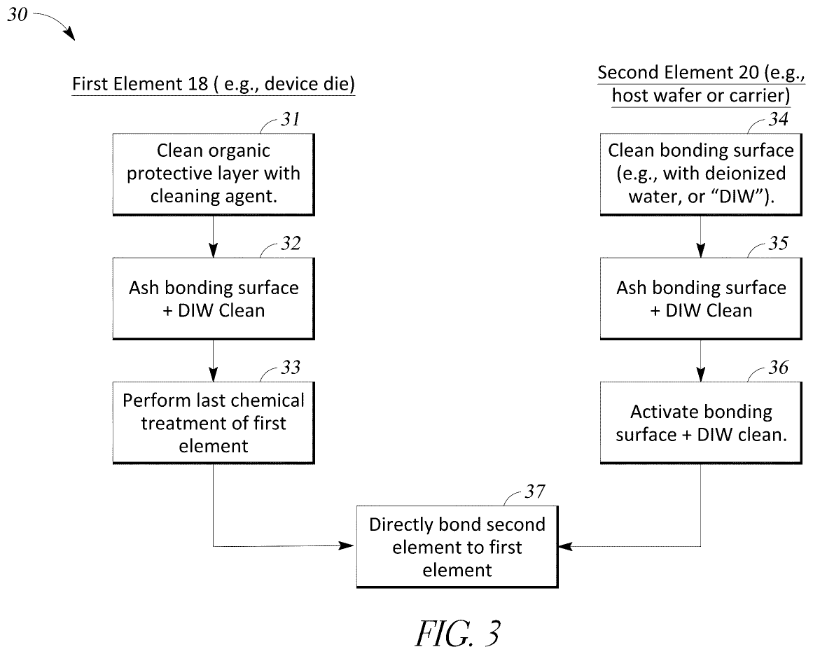

FIG. 3 is a flowchart illustrating an example process 30 for forming a bonded structure 26. In FIG. 3, the last chemical treatment is performed on the first element 28 after ashing, but is not performed on the second element 20. Rather, the second element 20, which can comprise a host wafer or carrier, can be activated and rinsed with DIW without being exposed to a last chemical treatment. Sufficiently strong direct bonding can occur when only the second element 20 is activated and when only the first element 18 is subjected to the last chemical treatment T. The elements 18, 20 can be directly bonded without an intervening liquid treatment being applied to the first element 18 between the last chemical treatment and the direct bonding.

In FIG. 3, a suitable protective material, for example an organic protective layer (e.g., a photoresist), can be formed on the bonding surface of the first element, which can comprise a wafer. After providing the protective layer, the first element 18 may be mounted on a dicing sheet or dicing layer for a die singulation operation. The first element 18 with protective layer can be singulated along saw streets to form a plurality of singulated elements 18. In other applications, the first element 18 may be mounted on the dicing layer prior the application of the protective layer. In this example, the protective layer may be disposed on portions of the dicing sheet. Beneficially, the protective layer can protect the activated bonding surface from debris or damage during the singulation process (and other processes). As shown in block 31 of FIG. 3, the protective layer can be removed with a cleaning agent. In some embodiments, the cleaned singulated elements 18 may be further ashed (e.g., exposed to an oxygen plasma) in a block 32 to remove any unwanted residues prior to performing the last chemical treatment T on the bonding surface of the singulated dies. In a block 33, the last chemical treatment T can be applied to the ashed bonding surface of the first element 18, as explained above in connection with FIGS. 2A-2D. The last chemical treatment T of block 33 can utilize any of the gas-containing species S explained above.

Similarly, the bonding surface of the second element 20 may be cleaned in block 34 and ashed in block 35 to remove unwanted residues on the bonding surface. In some embodiments, as shown in block 36, the bonding surface of the second element 20 may be activated and rinsed with DIW prior to the bonding operation. In block 37, the first and second elements can be directly bonded without an intervening adhesive as explained above.

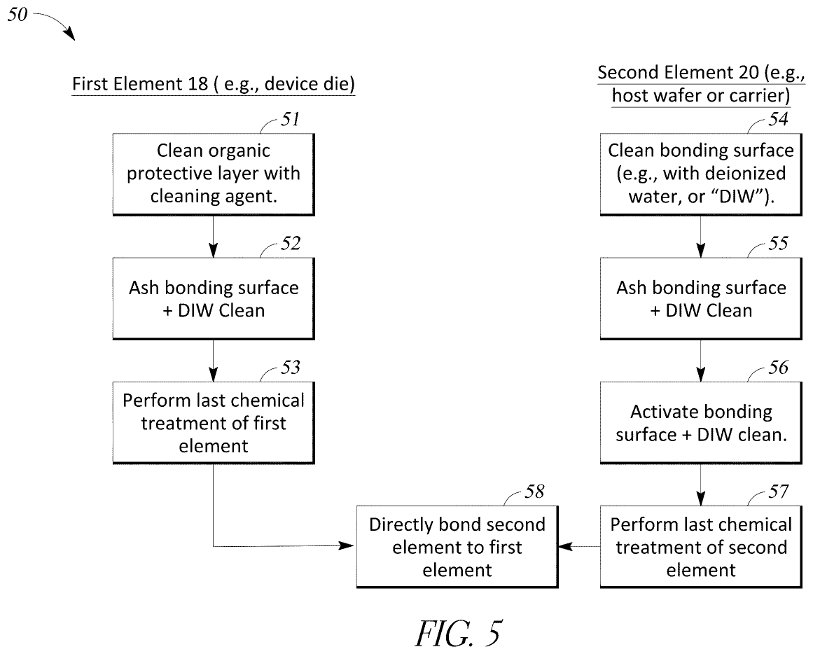

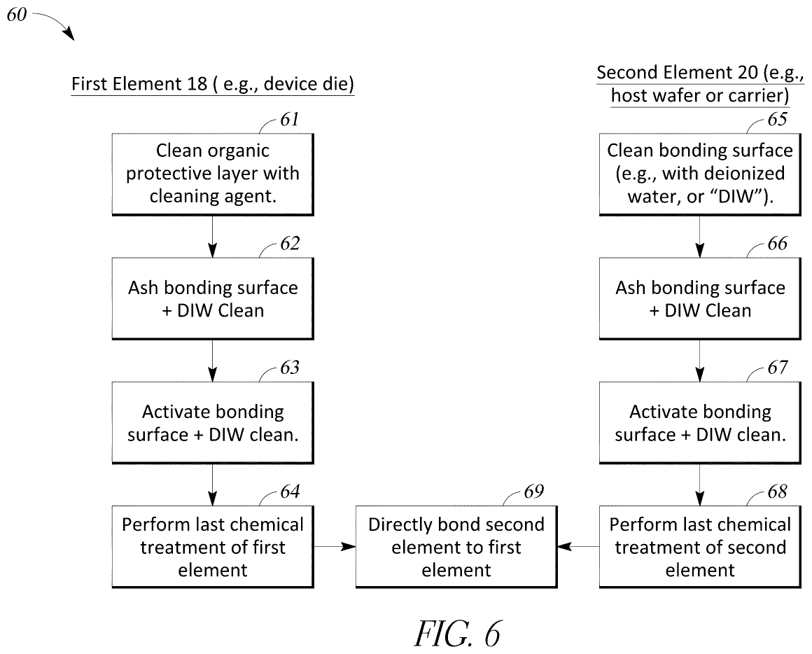

In the example of FIG. 3, only the singulated bonding surface of the first element 18 is exposed to the last chemical treatment T, while the second element 20 can be rinsed with DIW and may not undergo the last chemical treatment T between the activation of block 36 and the bonding of block 37. In other implementations, the bonding surfaces of the first singulated element 18 and the bonding surface of the second singulated element 20 can both be exposed to the last chemical treatment T before the bonding operation of block 37 as shown below in FIG. 5. Also, in some embodiments, although not illustrated in FIG. 3, the bonding surface of the first singulated element 18 may be activated prior to the last chemical treatment T of block 33. Accordingly, in some embodiments, only the second element 20 is activated prior to bonding, while in other embodiments, both the first and second elements 18, 20 may be activated prior to bonding. In still other embodiments, only the first element 18 may be activated prior to the bonding.

As described herein, the bonding surface of the first singulated element 18 may be treated with a last chemical species A and the bonding surface of the second singulated element 20 can be treated with a last chemical species B prior to the bonding operation of step 37. In this example, species A is a different chemical moiety from species B. As an example, species A may be acidic (e.g., mildly acidic) and species B may be alkaline (e.g., mildly alkaline). Species A may comprise more than one chemical moeity, and species B may comprise more than one chemical moeity. For example, species A may comprise a blend of very dilute buffer HF and very dilute phosphoric acid or very dilute boric acid, while species B may comprise a blend of very dilute tetramethyl ammonium hydroxide with very dilute dimethylamine borane. In some embodiments, the last chemical treatment T can apply species A (which can include one or multiple components) on the first element 18, and the second element 20 may not undergo the last chemical treatment, or vice versa. In some embodiments, the last chemical treatment T can apply species B (which can include one or multiple components) on the first element 18, and the second element 20 may not undergo the last chemical treatment T, or vice versa. Still other combinations may be suitable. The last chemical treatment T may be selected such that it does not substantially roughen the smooth bonding surface of the dielectric layer and does not substantially etch the pad metal to form an excessive recess over the pad metal. As explained above, an excessive pad recess can form a recess that is too deep such that pad-to-pad bonding may not form at the appropriate annealing conditions (e.g., annealing temperature and times). Thus, the appropriate chemical moieties may be selected for the formulation of the last treatment chemicals or chemistries.

After the bonding operation, the bonded elements may be annealed at a higher temperature to increase the bond strength of the interface between the first and second elements.

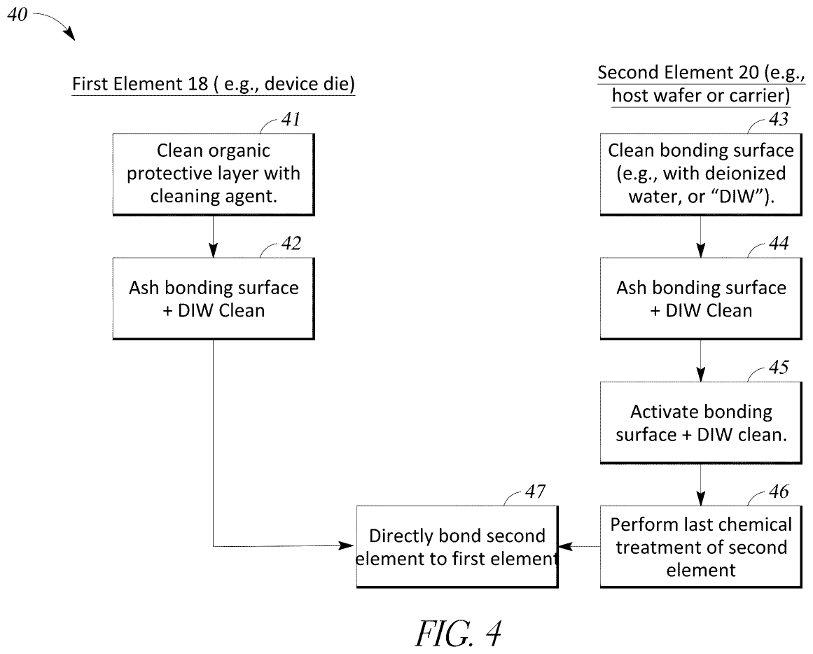

FIG. 4 is a flowchart illustrating another example method 40 for forming a bonded structure 26. Unless otherwise noted, the steps of the method 40 of FIG. 4 may be generally similar to those set forth about in connection with FIGS. 2A-3. For example, the protective layer of first element 18 can be cleaned with a cleaning agent in a block 41, and ashed (and DIW cleaned) in a block 42. The bonding surface of the second element 20 can be cleaned in a block 43 and ashed (and DIW cleaned) in a block 44. The bonding surface of the second element 20 can be activated in a block 45. The last chemical treatment T can be performed on the activated bonding surface of the second element 20. In FIG. 4, the first element 18 may not be activated or exposed to the last chemical treatment before direct bonding in a block 47. Rather, the bonding layer of the second element 20 can be activated and, subsequently, the activated bonding surface of the second element 20 can be exposed to the last chemical treatment before direct bonding in block 47.

FIG. 5 is a flowchart illustrating another example method 50 for forming a bonded structure 26. Unless otherwise noted, the steps of the method 50 of FIG. 5 may be generally similar to those set forth about in connection with FIGS. 2A-4. For example, the protective layer of first element 18 can be cleaned with a cleaning agent in a block 51, and ashed (and DIW cleaned) in a block 52. In block 53 of FIG. 5, the first element 18 may not be activated but may be exposed to the last chemical treatment after ashing of block 52. The bonding surface of the second element 20 can be cleaned in a block 54 and ashed (and DIW cleaned) in a block 55. The second element 20 can be activated in a block 56, and, subsequently the last chemical treatment T can be performed in a block 57 before direct bonding in a block 58. After exposing the first and second elements 18, 20 to the last chemical treatments T, the first and second elements 18, 20 can be directly bonded in block 58 without an intervening liquid treatment between the last chemical treatments of blocks 53, 57 and the direct bonding of block 58.

FIG. 6 is a flowchart illustrating another example process 60 for forming a bonded structure 26. Unless otherwise noted, the steps of the method 60 of FIG. 6 may be generally similar to those set forth about in connection with FIGS. 2A-5. For example, the protective layer of first element 18 can be cleaned with a cleaning agent in a block 61, and ashed (and DIW cleaned) in a block 62. In the embodiment of FIG. 6, both the bonding layers of the first and second elements 18, 20 can be activated and, subsequently, the activated surfaces of the first and second elements can be exposed to respective last chemical treatments T. For example, the bonding surface of the first element 18 can be activated (and DIW cleaned) in a block 63, and the activated bonding surface of the first element 18 can be exposed to the last chemical treatment T in a block 64. The bonding surface of the second element 20 can be cleaned in a block 65 and ashed (and DIW cleaned) in a block 66. The second element 20 can be activated in a block 67, and, subsequently the last chemical treatment T can be performed in a block 68 to the second element 20. The first and second elements 18, 20 can be directly bonded in a block 69 without an intervening liquid treatment between the last chemical treatments of blocks 64, 68 and the direct bonding of block 69.

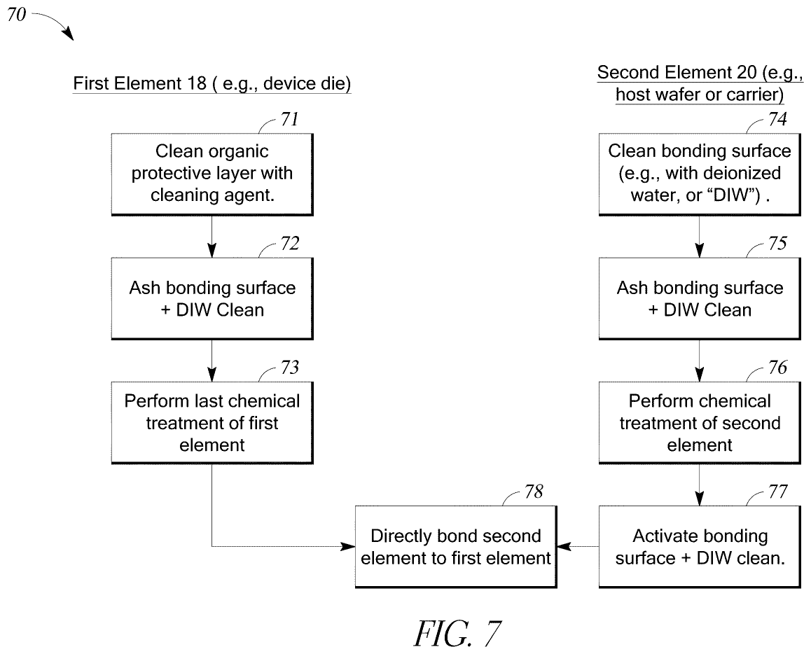

FIG. 7 is a flowchart illustrating another example process 70 for forming a bonded structure 26. Unless otherwise noted, the steps of the method 70 of FIG. 7 may be generally similar to those set forth about in connection with FIGS. 2A-6. For example, the protective layer of first element 18 can be cleaned with a cleaning agent in a block 71, and ashed (and DIW cleaned) in a block 72. In block 73 of FIG. 7, the first element 18 can be exposed to the last chemical treatment T after ashing and before directly bonding without an intervening treatment (e.g., without an intervening liquid treatment).

The bonding surface of the second element 20 can be cleaned in a block 74 and ashed (and DIW cleaned) in a block 75. In a block 76, the bonding layer of the second element 20 can be exposed to a chemical treatment after the ashing of block 75. The chemical treatment of block 76 may be similar to the last chemical treatment described above in connection with FIGS. 2A-6, except, in a block 77, the bonding layer of the second element 20 can be activated after the chemical treatment of block 76. Thus, in the embodiment of FIG. 7, the bonding surface of the second element 20 can be exposed to the glass-forming species S described above in the chemical treatment of block 76 before activation. The first and second elements can be directly bonded in a block 78.

After the treatment steps, the treated bonding surface of the first and second elements 18, 20 can be directly bonded and annealed at higher temperature to increase the bond strength of the interface 27 between the bonded elements 18, 20. For die to die (D2D) or element-to-element stacking operations, an additional die may be bonded on a bonding surface formed on the backside of the first or second elements 18, 20. Bonding a third element (not shown) on the back surface of the first element 18 may comprise cleaning the backside of the first element 18, ashing or activating the bonding surface on the backside of the first element 18, and performing the last chemical treatment on the bonding surface of the singulated third element or the backside of the first element 18 (or to both surfaces), prior to bonding the third element on the backside of the first element 18. The stacked bonded elements may be annealed at higher temperature before subsequent operations. In one embodiment, the stacked bonded elements may not be annealed before subsequent process, and the stacked bonded elements may be thoroughly rinsed before subsequent operations.

As explained above, one of the subsequent operations for example may comprise of singulating the second element with stacked element or elements to form directly bonded stacked elements. Other subsequent operations may include forming conductive structures on the lower or upper surface of the bonded stacked elements. The conductive structure may comprise a planar conductor or a flowable conductor or both.

In one embodiment, a bonding method can include: polishing a first bonding layer of a first element for direct bonding, the first bonding layer comprises a first conductive pad and a first non-conductive bonding region; after the polishing, performing a last chemical treatment of the polished first bonding layer; and after performing the last chemical treatment, directly bonding the first bonding layer of the first element to a second bonding layer of a second element without an intervening adhesive, including directly bonding the first conductive pad to a second conductive pad of the second bonding layer and directly bonding the first non-conductive bonding region to a second nonconductive bonding region of the second bonding layer, wherein no treatment or rinse is performed on the first bonding layer between performing the last chemical treatment and directly bonding.

In some embodiments, the method can include activating the first bonding layer for direct bonding. In some embodiments, the activating is performed before performing the last chemical treatment. In some embodiments, activating comprises exposing the first bonding layer to a plasma. In some embodiments, activating comprises exposing the first bonding layer to a nitrogen-containing plasma. In some embodiments, the first bonding layer comprises silicon oxide or silicon carbonitride. In some embodiments, activating comprises exposing the first bonding layer to an oxygen-containing plasma. In some embodiments, the first bonding layer comprises silicon nitride or silicon carbonitride. In some embodiments, performing the last chemical treatment comprises exposing the first bonding layer to a chemical species comprising at least one of boron, phosphorus, manganese, arsenic, peroxide, selenium, carbon, and fluorine or fluoride source. In some embodiments, a concentration of the chemical species is in a range of 1 ppm to 1,000 ppm. In some embodiments, a concentration of the chemical species is in a range of 1 ppm to 500 ppm. In some embodiments, performing the last chemical treatment comprises exposing the first bonding layer to a source of boron. In some embodiments, performing the last chemical treatment comprises exposing the first bonding layer to very dilute borane dimethylamine (BDMA). In some embodiments, a concentration of the BDMA is in a range of 5 ppm to 10,000 ppm. In some embodiments, performing the last chemical treatment comprises exposing the first bonding layer to boric acid. In some embodiments, performing the last chemical treatment comprises exposing the first bonding layer to very dilute phosphoric acid. In some embodiments, a concentration of the phosphoric acid is in a range of 5 ppm to 10,000 ppm. In some embodiments, performing the last chemical treatment comprises exposing the first bonding layer to a chemical treatment comprising very dilute buffered hydrofluoric acid (BHF). In some embodiments, a pH of the BHF is in a range of 4 to 6.5. In some embodiments, the last chemical treatment has a pH of at least 3.1. In some embodiments, the last chemical treatment has a pH of at least 3.3. In some embodiments, the last chemical treatment has a pH in a range of 3.3 to 9.5. In some embodiments, the last chemical treatment has a pH in a range of 3.3 to 4. In some embodiments, performing the last chemical treatment comprises exposing the first bonding layer to a chemical treatment comprising tetramethyl ammonium hydroxide. In some embodiments, the last chemical treatment has a pH in a range of 7 to 11. In some embodiments, the last chemical treatment has a pH in a range of 7 to 9.8. In some embodiments, a concentration of the tetramethyl ammonium hydroxide is less than 55 ppm. In some embodiments, the concentration of the tetramethyl ammonium hydroxide is less than 48 ppm. In some embodiments, a concentration of the tetramethyl ammonium hydroxide is in a range of 5 ppm to 45 ppm. In some embodiments, a concentration of the tetramethyl ammonium hydroxide is in a range of 5 ppm to 35 ppm. In some embodiments, performing the last chemical treatment comprises exposing the first bonding layer to a chemical treatment comprising one or more of tetramethylammonium hydroxide (C₄H₁₂N), tert-butylammonium hydroxide, tetraethylammonium hydroxide, ethyltrimethylammonium hydroxide, boric anhydride, boric acid, borane-ammonia (H₆BN), borane trimethylamine complex, borane dimethyl amine complex (C₂H₁₀BN), tetrahydroxydiboron solution, mannitol (C₆H₁₄O₆), and ascorbic acid (C₆H₈O₆). In some embodiments, the first bonding layer comprises a first plurality of conductive contact pads including the first conductive contact pad, wherein the second bonding layer comprises a second plurality of conductive contact pads including the second conductive contact pad, and wherein directly bonding comprises directly bonding the first and second pluralities of conductive contact pads to one another without an adhesive. In some embodiments, the method can include activating the second bonding layer before directly bonding. In some embodiments, the method can, after the activating the second bonding layer, performing a last chemical treatment of the second bonding layer. In some embodiments, the directly bonding is performed without activating the second bonding layer. In some embodiments, the first element comprises a wafer, the method further comprising providing a protective layer over the first bonding layer and singulating the wafer into a plurality of singulated integrated device dies. In some embodiments, the method can include removing the protective layer before performing the last chemical treatment.

In another embodiment, a bonding method can include: polishing a first bonding layer of a first element for direct bonding; after the polishing, performing a last treatment of the polished first bonding layer, the last treatment comprising a solution including at least one of boron, phosphorus, manganese, selenium, carbon, a peroxide and arsenic; and after performing the last treatment, directly bonding the first bonding layer of the first element to a second bonding layer of a second element without an intervening adhesive.

In some embodiments, no liquid treatment is performed on the first bonding layer between performing the last chemical treatment and directly bonding. In some embodiments, the last chemical treatment comprises a glass-forming species having a concentration in a range of 5 ppm to 10,000 ppm.

In another embodiment, a bonding method can include: activating a first bonding layer of a first element for direct bonding; after the activating, performing a last treatment of the activated first bonding layer to the polished first bonding layer; and after performing the last treatment, directly bonding a first nonconductive region of the first bonding layer of the first element to a second nonconductive region of a second bonding layer of a second element without an intervening adhesive and directly bonding a first contact pad of the first bonding layer to a second contact pad of the second bonding layer without an intervening adhesive.

In some embodiments, no liquid treatment is performed on the first bonding layer between performing the last chemical treatment and directly bonding. In some embodiments, no chemical treatment is performed on the first bonding layer between performing the last chemical treatment and directly bonding. In some embodiments, a method can include a bonded structure formed by the bonding methods described herein. In some embodiments, the first and second elements are directly bonded along a bonding interface, the bonding interface comprising sediment from the last chemical treatment. In some embodiments, the sediment comprises at least a local peak concentration of a dilute chemical used in the chemical treatment. In some embodiments, the sediment comprises at least one of boron, phosphorus, manganese, arsenic and fluorine.

In another embodiment, a bonding method can include: forming a bonding surface on a first element; coating the bonding surface of the first element with a protective layer; singulating the first element and the protective layer on a dicing sheet; cleaning the protective layer from the bonding surface of the first element while the first element is still mounted on the dicing sheet; exposing the cleaned surfaces of the singulated first elements to plasma; performing a last chemical treatment of the polished first bonding layer; and after performing the last chemical treatment, directly bonding the first bonding layer of the first element to a second bonding layer of a second element without an intervening adhesive, wherein no deionized water (DIW) rinse is performed on the first bonding layer between performing the last chemical treatment and directly bonding.

In some embodiments, the last chemical treatment does not degrade the bonding surface of the first element. In some embodiments, the plasma comprises oxygen plasma, water vapor plasma, or nitrogen plasma. In some embodiments, the plasma treated bonding surface area of the first element is rinsed with DIW before bonding operation. In some embodiments, the bonding surface of the first element is rinsed with DIW before performing the last chemical treatment. In some embodiments, the method can include exposing the bonding surface of the second element to plasma before bonding, wherein the plasma comprises oxygen plasma, water vapor plasma, or nitrogen plasma. In some embodiments, the bonding surface area of the first element is smaller than that of the second element. In some embodiments, the method can include annealing the bonded structure at a temperature higher than room temperature.

In another embodiment, a bonding method can include: forming a bonding surface on a first element; forming a bonding surface on a second element; exposing the bonding surfaces of at least one of the first and second elements to a plasma; performing a first last chemical treatment on the bonding surface of the first element; performing a second last chemical treatment on the bonding surface of the second element; directly bonding respective nonconductive regions of the first and second elements without an intervening adhesive; and directly bonding respective conductive pads of the first and second elements without an intervening adhesive.

In some embodiments, the first chemical treatment is different from the second chemical treatment. In some embodiments, the method can include annealing the bonded structure at a temperature higher than room temperature. In some embodiments, the first last chemical treatment comprises an acidic chemical species and the second last chemical treatment comprises an alkaline chemical species. In some embodiments, the second element is larger than the first element, the method further comprising singulating the larger second element to form bonded plurality of elements.

In another embodiment, a bonded structure can include: a first element having a first contact pad at least partially embedded in a first nonconductive region; and a second element at least partially embedded in a second nonconductive region, the first and second elements directly bonded to one another along a bond interface, the first and second nonconductive regions directly bonded without an adhesive, the first and second contact pads directly bonded without an adhesive, wherein the bond interface comprises sediment from a last chemical treatment to at least one of the first and second nonconductive regions.

In some embodiments, the sediment comprises at least a local peak concentration of a dilute chemical used in the last chemical treatment. In some embodiments, the sediment comprises at least one of boron, phosphorus, manganese, arsenic, selenium, and fluorine. In some embodiments, the sediment comprises carbon.

All of these embodiments are intended to be within the scope of this disclosure. These and other embodiments will become readily apparent to those skilled in the art from the following detailed description of the embodiments having reference to the attached figures, the claims not being limited to any particular embodiment(s) disclosed. Although this certain embodiments and examples have been disclosed herein, it will be understood by those skilled in the art that the disclosed implementations extend beyond the specifically disclosed embodiments to other alternative embodiments and/or uses and obvious modifications and equivalents thereof. In addition, while several variations have been shown and described in detail, other modifications will be readily apparent to those of skill in the art based upon this disclosure. It is also contemplated that various combinations or sub-combinations of the specific features and aspects of the embodiments may be made and still fall within the scope. It should be understood that various features and aspects of the disclosed embodiments can be combined with, or substituted for, one another in order to form varying modes of the disclosed implementations. Thus, it is intended that the scope of the subject matter herein disclosed should not be limited by the particular disclosed embodiments described above, but should be determined only by a fair reading of the claims that follow.

What is claimed is:

1. A bonding method comprising:
polishing a first bonding layer of a first element for direct bonding, the first bonding layer comprises a first conductive pad and a first non-conductive bonding region;
after the polishing, performing a last chemical treatment of the polished first bonding layer; and
after performing the last chemical treatment, directly bonding the first bonding layer of the first element to a second bonding layer of a second element without an intervening adhesive, including directly bonding the first conductive pad to a second conductive pad of the second bonding layer and directly bonding the first non-conductive bonding region to a second nonconductive bonding region of the second bonding layer, wherein no treatment or rinse is performed on the first bonding layer between performing the last chemical treatment and directly bonding.
